(19) United States
(12) Patent Application Publication
(10) Pub. No.: US 2019/0103756 A1
(43) Pub. Date: Apr. 4, 2019

(54) POWER STORAGE SYSTEM, APPARATUS AND METHOD FOR CONTROLLING CHARGE AND DISCHARGE, AND PROGRAM

(71) Applicant: NEC Corporation, Tokyo (JP)

(72) Inventor: Hideyuki HASEGAWA, Tokyo (JP)

(73) Assignee: NEC Corporation, Tokyo (JP)

(21) Appl. No.: 16/086,897

(22) PCT Filed: Feb. 23, 2017
(86) PCT No.: PCT/JP2017/006895

§ 371 Date: Sep. 20, 2018

(30) Foreign Application Priority Data
Mar. 23, 2016 (JP) 2016-059286

(51) Int. Cl. H02J 7/35; H01L 31/02; H02J 7/02; H02M 7/525; H02J 7/00

(52) U.S. Cl. CPC H02J 7/35; H01L 31/02008; H02J 7/007; H02M 7/525; H02J 7/022

(57) ABSTRACT

The charging and discharging control apparatus is an apparatus that controls charging and discharging of a power storage apparatus. The power storage apparatus is connected to an AC power line and is connectable to a specific load without involving the AC power line. The AC power line is connected to a power system, is connected to a direct-current power line through a DC/AC conversion apparatus (PV-PCS), and is connectable to a general load. The charging and discharging control apparatus includes an acquisition unit that acquires information on a direction of a current in the AC power line, and a control unit that supplies electric power to the power storage apparatus when a current is flowing from the AC power line to the power system.

### TECHNICAL FIELD

The present invention relates to a power storage system, an apparatus and a method for controlling charge and discharge, and a program.

### BACKGROUND ART

Patent Document 1 describes an example of a power storage apparatus that is interconnected with a commercial power supply. The power storage apparatus of Patent Document 1 stores the electric power of the commercial power supply and discharges the stored electric power. At a time of discharging output of the power storage apparatus, a voltage and current of the power storage apparatus and an alternating current output voltage and current are measured, and from the measured values, a direct current output current of the power storage apparatus is controlled such that a ratio between a direct current output electric power and an alternating current output effective electric power is substantially maximized.

Patent Document 2 describes an example of a power supply system which performs a so-called peak shift operation, in which the power output of a photovoltaic power generation apparatus is stored in a power storage apparatus during a daytime zone and discharged during a nighttime zone to supply electric power to a load apparatus. In the system described in Patent Document 2, stable power supply to the load apparatus is implemented by predicting a charging and discharging amount of the power storage apparatus from the demand prediction data of the load apparatus and power generation output prediction data predicted using weather forecast data, and based on the predicted values, controlling a power generation amount of the power generation apparatus or suppressing the electric power consumption of an adjustment load apparatus.

Patent Document 3 describes an example of a power supply system that is connected to a power system. In this system, charging and discharging control of the power storage apparatus is performed, thereby more effectively suppressing fluctuation of the output electric power to a power system side.

Patent Document 4 describes a power supply apparatus that stably charges a secondary battery in a situation where electric power generated from a solar cell fluctuates due to changes in an intensity of sunshine or ambient temperature.

### RELATED DOCUMENT

### Patent Document

[Patent Document 1] Japanese Laid-open Patent Publication No. 2004-112954

[Patent Document 2] Japanese Laid-open Patent Publication No. 2013-176234

[Patent Document 3] International Publication No. 2011/122669

[Patent Document 4] Japanese Laid-open Patent Publication No. 2005-328662

### SUMMARY OF THE INVENTION

### Technical Problem

The above-mentioned Patent Documents describe a system including a photovoltaic power generation system and a power storage apparatus or a power storage apparatus (Patent Document 1) for storing electric power from the system, but do not describe a configuration for installing the power storage apparatus afterwards in order to make effective use of surplus electric power of the existing photovoltaic power generation system.

There is a possibility that, when the power storage apparatus is retrofitted to the existing system, an installation cost becomes high, a processing of coordinating with the operation of the photovoltaic power generation system is required, the processing and structure become complicated, or the charging and discharging efficiency of the storage battery is lowered.

The present invention has been made in view of such circumstances, and an object of the present invention is to provide a power storage system that efficiently utilizes surplus electric power of a photovoltaic power generation system, an apparatus and a method for controlling charge and discharge, and a program.

### Solution to Problem

In each aspect of the present invention, in order to solve the above-mentioned problems, the following configurations are respectively adopted.

A first aspect relates to a power storage system.

The power storage system in the first aspect includes:

a power storage unit; and

a control unit that controls charging and discharging of the power storage unit,

in which the power storage unit is connected to an alternating current (AC) power line and is capable of supplying electric power to a specific load without involving the AC power line,

the AC power line is connected to a power system, is connected to a direct current (DC) power generation apparatus through a DC/AC conversion apparatus, and is connectable to a general load, and

the control unit supplies electric power to the power storage unit when a current is flowing from the AC power line to the power system.

A second aspect relates to a charging and discharging control apparatus.

The charging and discharging control apparatus in the second aspect is

a charging and discharging control apparatus that controls charging and discharging of a power storage apparatus,

the power storage apparatus being connected to an AC power line, and

the AC power line being connected to a power system, being connected to a DC power generation apparatus through a DC/AC conversion apparatus, and being connectable to a load,

the charging and discharging control apparatus including:

an acquisition unit that acquires information on a direction of a current in the AC power line; and

a control unit that supplies electric power to the power storage unit when a current is flowing from the AC power line to the power system.

A third aspect relates to a control method performed by a charging and discharging control apparatus, which is executed by at least one computer.

The control method performed by the charging and discharging control apparatus in the third aspect is

a method of controlling a charging and discharging control apparatus connected to a power storage apparatus capable of charging electricity generated by a DC power generation apparatus,

the power storage apparatus being connected to an AC power line, and being capable of supplying electric power to a specific load without involving the AC power line, and

the AC power line being connected to a power system, being connected to the DC power generation apparatus through a DC/AC conversion apparatus, and being connectable to a general load,

the control method performed by the charging and discharging control apparatus including

supplying electric power to the power storage apparatus when a current is flowing from the AC power line to the power system.

Note that, another aspect of the present invention may be a program causing the at least one computer to execute the method in the third aspect, or may be a computer-readable storage medium storing the program. The storage medium includes a non-transitory tangible medium.

The computer program includes a computer program code which, when executed by a computer, causes the computer to execute the control method on the charging and discharging control apparatus.

Note that, those obtained by converting any combination of the foregoing components and the representation of the present invention between a method, an apparatus, a system, a storage medium, a computer program, and the like are also effective as aspects of the present invention.

Various types of components of the present invention are not necessarily required to be present individually and independently, but a plurality of components may be formed as one member, one component may be formed by a plurality of members, a certain component may be a portion of another component, a portion of a certain component and a portion of another component may overlap each other, or the like.

A plurality of procedures are described in order in the method and the computer program according to the present invention, but the order of the description is not intended to limit the order of the execution of the plurality of procedures. Therefore, when the method and the computer program of the present invention are executed, the order of the plurality of procedures may be changed within the range of not causing any problem in terms of the contents.

Further, the plurality of procedures of the method and the computer program according to the present invention are not limited to be individually executed at timings different from each other. Therefore, another procedure may occur during the execution of a certain procedure, the execution timing of a certain procedure and a portion or all of the execution timings of another procedure may overlap each other, or the like.

### Advantageous Effects of Invention

According to each aspect described above, it is possible to provide a power storage system that efficiently utilizes surplus electric power of a photovoltaic power generation system, an apparatus and a method for controlling charge and discharge, and a program.

### BRIEF DESCRIPTION OF THE DRAWINGS

The object and other objects, and features and advantages described above will become more apparent by preferred example embodiments described below and the following drawings associated therewith.

FIG. 1 is a schematic block diagram illustrating a configuration example of a photovoltaic power generation system.

FIG. 2 is a schematic block diagram illustrating a configuration example of a power storage system according to an example embodiment of the present invention.

FIG. 3 is a functional block diagram logically illustrating a configuration of a charging and discharging control apparatus according to an example embodiment of the present invention.

FIG. 4 is a diagram illustrating an example of the transition of the charge capacity over time by charging and discharging control of the storage battery of the power storage system of the example embodiment.

FIG. 5 is a diagram for explaining charging and discharging control of a storage battery of the power storage system of the example embodiment.

FIG. 6 is a diagram illustrating an example of the configuration of a computer that implements the charging and discharging control apparatus of the example embodiment.

FIG. 7 is a flowchart illustrating an example of operations of the charging and discharging control apparatus according to the example embodiment.

FIG. 8 is a flowchart illustrating an example of operations of the charging and discharging control apparatus according to the example embodiment.

FIG. 9 is a flowchart illustrating an example of an operation at a time of charging of the charging and discharging control apparatus of the example embodiment.

FIG. 10 is a flowchart illustrating an example of an operation at a time of discharging of the charging and discharging control apparatus of the example embodiment.

FIG. 11 is a diagram for explaining charging and discharging control of a storage battery of the power storage system of the example embodiment.

FIG. 12 is a schematic block diagram illustrating a configuration example of a charging and discharging control apparatus according to an example of the present invention.

FIG. 13 is a schematic block diagram illustrating a configuration example in a case where the charging and discharging control apparatus of the example of the present invention is utilized as an Uninterruptible Power Supply (UPS).

### DESCRIPTION OF EMBODIMENTS

Hereinafter, example embodiments of the present invention will be described with reference to the drawings. In all the drawings, same components are denoted by the same reference numerals, and descriptions thereof will not be repeated.

### First Example Embodiment

A power storage system, an apparatus and a method for controlling charge and discharge, and a program according to a first example embodiment of the present invention will be described below.

The charging and discharging control apparatus of the example embodiment controls charging and discharging of a lithium ion secondary battery.

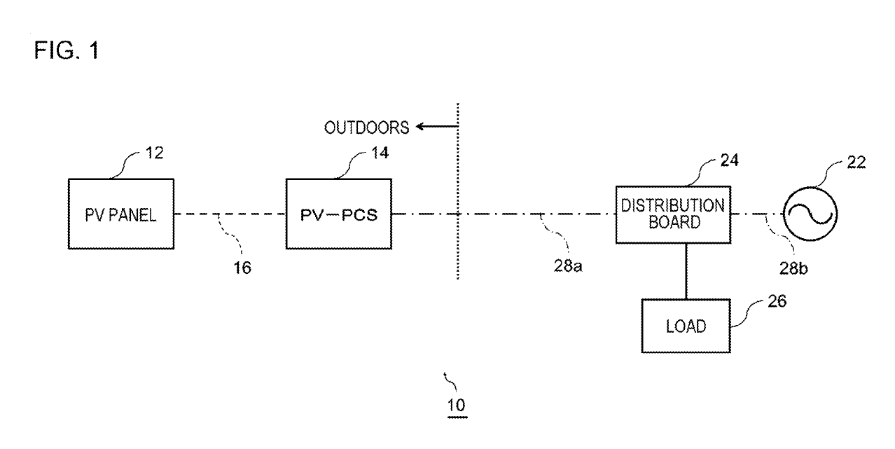

FIG. 1 is a schematic block diagram illustrating a configuration example of a photovoltaic (PV) system 10.

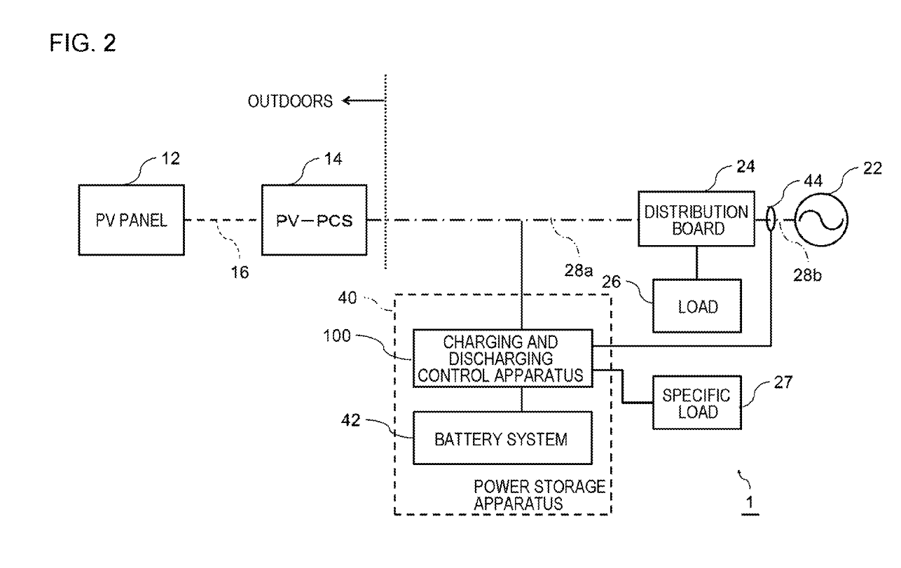

FIG. 2 is a schematic block diagram illustrating a configuration example of the power storage system 1 according to the example embodiment of the present invention. The power storage system 1 in FIG. 2 illustrates a configuration after a power storage apparatus 40 is added to an AC power line 28 (28a and 28b) side of the existing PV system 10 in FIG. 1.

In each drawing of the present specification, configurations of portions that are not related to the spirit of the invention are not described and not illustrated.

The existing PV system 10 in FIG. 1 includes a PV panel 12, a Power Conditioning System (PV-PCS) 14, a distribution board 24, and a load 26. In the example embodiment, it is considered that the PV panel 12 and the PV-PCS 14 are installed outdoors, and the distribution board 24 and the load 26 are installed indoors. This is only illustrative, and the PV-PCS 14 may be installed indoors, or the distribution board 24 and the load 26 may be installed outdoors.

The PV panel 12 and the PV-PCS 14 are connected by a DC power line 16 (indicated by a broken line).

The PV-PCS 14, the distribution board 24, and a power system 22 are connected by an AC power line 28 (28a and 28b) (indicated by a one-dotted chain line). A load 26 is further connected to the AC power line 28 (28a and 28b) through the distribution board 24.

The PV panel 12 includes a plurality of solar cells that receive solar light energy and convert it into electricity and is protected with tempered glass, acrylic resin, or the like, and for example, is installed on a roof of a residence.

A direct current generated by the PV panel 12 is input to the PV-PCS 14 through the DC power line 16. The PV-PCS 14 has a function of converting the direct current generated by the PV panel 12 into an alternating current generally used by home appliances (load 26). In the example embodiment, the PV-PCS 14 performs a Maximum Power Point Tracking (MPPT) control of the PV panel 12, and also has a function of controlling the operation of the PV panel 12. For example, the PV-PCS 14 receives a power output suppression control signal (hereinafter, also referred to as a PV power output suppression signal) for the PV panel 12, and suppresses the output of the PV panel 12 according to the control signal. The PV power output suppression signal includes, for example, an instruction to suppress an output to a predetermined ratio (%) of the rated power output of the PV-PCS 14.

The load 26 is at least one of various pieces of electrical equipment such as an air conditioner, a lighting apparatus, a refrigerator, a television, a microwave oven, a hairdryer, a personal computer, a game machine, a telephone, a water heater, an electric car, and a plug-in hybrid electric vehicle, and is not particularly limited thereto.

Electricity is supplied from the power system 22 to the distribution board 24 of the customer's house through a power transmission network, and electricity is distributed to each load 26 through the distribution board 24.

The electricity generated by the PV panel 12 is input to the PV-PCS 14 through the DC power line 16, is converted into an alternating current, and is output to the AC power line 28a. It passes through the AC power line 28a and may be supplied to the load 26 through the distribution board 24.

The electric power generated by the PV panel 12 may be consumed by the consumer's load 26 and a surplus of the electric power may also flow back to the power system 22 through the distribution board 24. However, in the example embodiment, the surplus electric power generated by the PV panel 12 is charged to the lithium ion secondary battery of a battery system 42 in the power storage apparatus 40 as much as possible without flowing back to the power system 22.

As illustrated in FIG. 2, the power storage system 1 of the example embodiment includes the power storage apparatus 40 and a clamp type AC sensor 44.

A charging and discharging control apparatus 100 of the example embodiment controls charging and discharging of the battery system 42 retrofitted into the existing PV system 10. The power storage apparatus 40 of the example embodiment includes the battery system 42 and the charging and discharging control apparatus 100. The power storage apparatus 40 is electrically connected to the AC power line 28a between the PV-PCS 14 and the distribution board 24. The power storage apparatus 40 in the example embodiment is installed indoors but may also be installed outdoors.

Note that in the example embodiment, the PV system 10 is described as an example but the present invention is not limited to photovoltaics and may also be applied to other renewable energy power generation systems that output DC power.

The battery system 42 includes at least one lithium ion rechargeable secondary battery (lithium-ion rechargeable battery) (hereinafter, also referred to as a “storage battery”) (not illustrated) and a Battery Management Unit (BMU) that manages the lithium ion secondary battery. The battery system 42 has an electric capacity to which the system may perform charging, as indicated by the rated capacity (kWh). The battery system 42 is controlled by the charging and discharging control apparatus 100 in charging and discharging of the storage battery.

In the example embodiment, it is considered that charging and discharging control is performed within a predetermined range with respect to a rated capacity of the storage battery in charging and discharging control of the storage battery although a detailed description thereof is not provided herein.

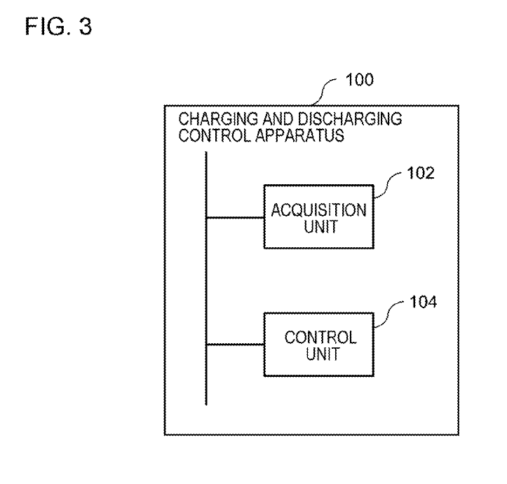

FIG. 3 is a functional block diagram logically illustrating the configuration of the charging and discharging control apparatus 100 according to the example embodiment of the present invention. Hereinafter, the configuration of the charging and discharging control apparatus 100 of the example embodiment will be described with reference to FIG. 2 and FIG. 3.

The charging and discharging control apparatus 100 of the example embodiment is an apparatus that controls charging and discharging of the power storage apparatus 40. The power storage apparatus 40 is connected to the AC power line 28 and is connectable to a specific load 27 without involving the AC power line 28. The AC power line 28 is connected to the power system 22 and is connected to the DC power line 16 through a DC/AC conversion apparatus (PV-PCS 14). Further, the AC power line 28 is connectable to a general load 26.

The charging and discharging control apparatus 100 includes an acquisition unit 102 that acquires information on a direction of the current in the AC power line 28, and a control unit 104 that supplies electric power to the storage apparatus 40 (at a time of electricity sale) when the current is flowing from the AC power line 28 to the power system 22.

Hereinafter, in the present specification, it is considered that a load connectable to the power storage apparatus 40 without involving the AC power line 28 is referred to as the specific load 27. The specific load 27 is distinguished from a general load 26 in that the general load 26 is connected through the distribution board 24 to the AC power line 28 and supplied with electric power from the AC power line 28.

In the present specification, “acquisition” includes at least one of: the own apparatus acquiring data or information stored in another apparatus or a storage medium (active acquisition), for example, receiving data or information by making a request or inquiry into another apparatus, or reading out data or information by having access to another apparatus or a storage medium, or the like; and inputting data or information output from another apparatus to the own apparatus (passive acquisition), for example, receiving distributed (or transmitted, push notified, and the like) data or information, or the like. The “acquisition” also includes selecting and acquiring from among the received data or information, or selecting and receiving the distributed data or information.

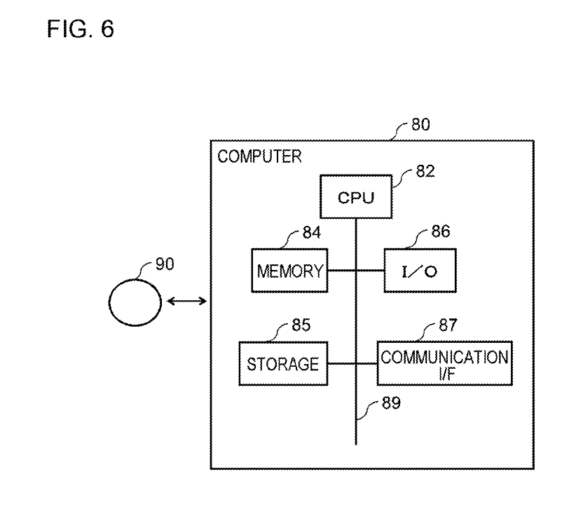

Further, the charging and discharging control apparatus 100 of the example embodiment may be accessibly connected to a storage apparatus 110 (not illustrated). The storage apparatus 110 may be included in the charging and discharging control apparatus 100 or may be an external apparatus of the charging and discharging control apparatus 100. In the example embodiment, the storage apparatus 110 may be implemented by a memory 84 or storage 85 of a computer 80 in FIG. 6 to be described later.

Hereinafter, each component of the charging and discharging control apparatus 100 in FIG. 3 will be described in detail.

The acquisition unit 102 acquires a current value and direction of a current flowing between the AC power line 28b and the power system 22. In the example of FIG. 2, for example, the clamp type AC sensor, that is, a Current Transformer (CT) 44 of FIG. 2 is attached to the AC power line 28b between the distribution board 24 and the power system 22, and the current value of the AC power line 28b is measured by the clamp type AC sensor 44. The acquisition unit 102 acquires the current value measured by the clamp type AC sensor 44 and acquires information on the direction of the current.

As described above, the control unit 104 controls charging and discharging of the power storage apparatus (battery system 42) based on the direction of the current in the AC power line 28b.

In detail, the control unit 104 performs control of charging a surplus (surplus electric power) remaining which is not consumed by the general load 26 and the specific load 27 out of electric power generated by the PV panel 12, to the power storage apparatus (storage battery of the battery system 42).

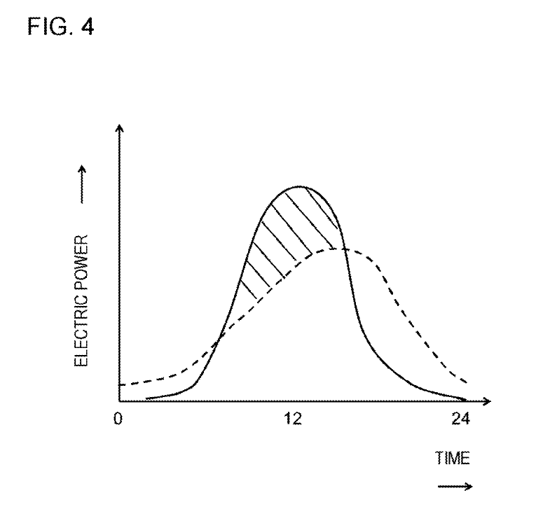

As illustrated in FIG. 4, a difference (hatched portion) between the power generation amount (indicated by a solid line) of the PV panel 12 at each time and the total consumption amount (indicated by a broken line) of the electric power of the general load 26 and the specific load 27 is the surplus electric power of the PV panel 12.

The control unit 104 may perform control of discharging the storage battery.

For example, instead of the electric power supplied from the power system 22 or the PV panel 12 to the specific load 27, the electric power charged to the storage battery may be discharged from the storage battery and supplied to the specific load 27.

In the example embodiment, it is considered that the electric power discharged from the storage battery is not caused to flow back to the power system 22 and is consumed by the specific load 27 of the customer.

In the example embodiment, the acquisition unit 102 acquires information on the direction of the current flowing through the AC power line 28b, and the control unit 104 controls the charging and discharging of the storage battery based on the information. However, the present invention is not limited thereto. As described below, configurations for performing charging and discharging control of the storage battery under various information or conditions are also not eliminated. A plurality of the followings may be combined without contradiction.

In the present invention, based on information indicating whether there is surplus in the electric power generated by the PV panel 12, it is possible to determine whether charging is possible.

The conditions for the control unit to determine whether charging is possible or not are exemplified below.

(a1) Charging is performed when the direction of the current in the AC power line 28b is from the distribution board 24 to the power system 22, that is, in a case where a backflow (electricity sale) to the power system 22 is generated.

(a2) Charging is performed using surplus exceeding a threshold value, in a case where the power generation amount from the PV panel 12 is equal to or larger than the threshold value.

(a3) Charging is performed using surplus electric power controlled to be suppressed in power output by the PV power output suppression signal.

In (a1) above, whether charging is possible or not is determined based on the direction of the current in the AC power line 28b.

Specifically, when the current in the AC power line 28b is directed from the distribution board 24 to the power system 22, charging of the storage battery is performed. When the direction of the current is not a direction from the distribution board 24 to power system 22, charging is not performed.

This configuration is the configuration of the example embodiment. The acquisition unit 102 acquires information on the direction of the current in the AC power line 28b (between the power system 22 and the distribution board 24). The direction of the current may be determined by a sign of positive or negative of the current value of the AC power line 28b. For example, it is considered that, in a case where a current flows in a direction from the power system 22 to the distribution board 24, a current value is a positive value, and in a case where a current flows in a direction from the distribution board 24 to the power system 22, a current value is a negative value. Since the direction of the flowing current and the positive and negative of the current value are determined according to the method of installing the clamp type AC sensor 44, under a determination condition according to an installed state of the clamp type AC sensor 44, a relationship between the direction of the current and the positive or negative of the current value is preset.

Here, since, in the case of an alternating current, the direction of the current changes with time, the current value is positive when an alternating current is zero degrees plus or minus 90 with respect to a phase of an AC voltage, that is, in the case where AC power is output in a direction from the power system 22 to the distribution board 24. On the other hand, the current value is negative when the alternating current is zero degrees plus or minus 90 or more, that is, in a case where AC power is output in a direction from the distribution board 24 to the power system 22.

Further, the control unit may control charging and discharging of the storage battery by using at least one of the plurality of conditions (b1) to (b5) as exemplified below in combination.

(b1) Charging/discharging is performed according to a predetermined first time zone in which the storage battery may be charged and a second time zone in which the storage battery may be discharged.

In this configuration, information on the first time zone and the second time zone is stored in the storage apparatus 110 in advance.

In the power storage apparatus 40 of the example embodiment, it is considered that the first time zone in which the storage battery may be charged, and the second time zone in which the storage battery may be discharged, are determined in advance. The first time zone is set from 6 o'clock to 18 o'clock and the second time zone is set from 18 o'clock to 6 o'clock on the next day.

The control unit 104 supplies the electric power discharged from the power storage apparatus 40 to the specific load 27 during a predetermined second time zone.

The control unit 104 supplies the electric power supplied from the power system 22 to the specific load 27, except during the predetermined second time zone.

It is considered that the charging and discharging control apparatus 100 has a clock (not illustrated) and acquires time information from the clock. The clock need not be included in the charging and discharging control apparatus 100 or may be an external apparatus of the charging and discharging control apparatus 100.

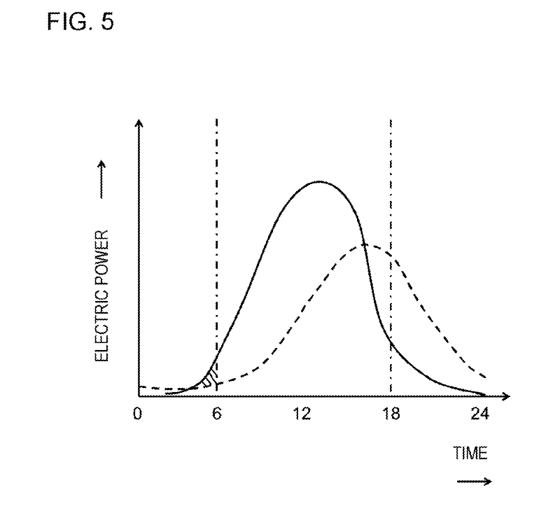

As illustrated in FIG. 5, even when the power generation amount of the PV panel 12, indicated by the solid line, exceeds a total power consumption amount of the general load 26 and the specific load 27, indicated by the broken line, surplus electric power (indicated by hatching in the figure) in the second time zone is not charged to the storage battery.

(b2) In a case where the storage battery is fully charged, charging is not performed.

In this configuration, the acquisition unit 102 may acquire information indicating that the storage battery is fully charged from the BMU of the battery system 42.

(b3) When the storage battery is charged to a predetermined ratio (%) or more of the storage capacity, charging is stopped.

In this configuration, a predetermined ratio (%) of the storage capacity of the storage battery is stored in the storage apparatus 110 in advance.

(b4) Control of charging and discharging of the storage battery is performed according to a situation of electricity purchase or electricity sale in the power system 22.

This configuration will be described in detail in an example embodiment as follows.

(b5) When a remaining power storage capacity of the storage battery is smaller than the first threshold value or an available capacity is equal to or larger than the second threshold value, discharge of the storage battery is stopped.

In this configuration, the acquisition unit 102 may acquire the information on the remaining power storage capacity or the available capacity of the storage battery from the BMU of the battery system 42. The threshold values are stored in the storage apparatus 110 in advance. Each threshold value may have a configuration to be updatable from the outside.

FIG. 6 is a diagram illustrating an example of a configuration of a computer 80 that implements the charging and discharging control apparatus 100 of the example embodiment.

The computer 80 of the present embodiment includes a Central Processing Unit (CPU) 82, a memory 84, a program 90 that implements the components of the charging and discharging control apparatus 100 loaded in the memory 84, a storage 85 that stores the program 90, an input/output (I/O) 86, and a network connection interface (communication I/F 87).

The CPU 82, the memory 84, the storage 85, the I/O 86, and the communication I/F 87 are connected with one another through a bus 89, and the whole charging and discharging control apparatus 100 is controlled by the CPU 82. However, a method of connecting the CPU 82 and the like with one another is not limited to bus connection.

The memory 84 is a memory such as a Random Access Memory (RAM) or a Read Only Memory (ROM). The storage 85 is a storage apparatus such as a hard disk, a Solid State Drive (SSD), or a memory card.

The storage 85 may be a memory such as a RAM or a ROM. The storage 85 may be provided inside the computer 80, or provided outside the computer 80 and wired or wirelessly connected to the computer 80 as long as the storage 85 is accessible to the computer 80. Alternatively, the storage 85 may be attachable and detachable to the computer 80.

By reading out and executing the program 90 stored in the storage 85 to the memory 84, the CPU 82 may implement each function of each unit of the charging and discharging control apparatus 100.

The I/O 86 performs input/output control of data and control signals between the computer 80 and other input/output apparatuses. The other input/output apparatuses include, for example, an input apparatus (not illustrated) such as a keyboard, a touch panel, a mouse and a microphone connected to the computer 80, an output apparatus (not illustrated) such as a display, a printer and a speaker, and an interface between these input/output apparatuses and the computer 80. Further, the I/O 86 may perform input/output control of data with a reading or writing apparatus (not illustrated) of another storage medium.

The communication I/F 87 is a network connection interface for performing communication between the computer 80 and an external apparatus. The communication I/F 87 is not necessarily required. The communication I/F 87 may be a network interface for connection to a wired line or network interface for connection to a wireless line. For example, the computer 80 that implements the charging and discharging control apparatus 100 may be connected to a HEMS through a network 3 using the communication I/F 87.

Each component of the charging and discharging control apparatus 100 of the example embodiment is implemented by any combination of hardware and software of the computer 80 in FIG. 6. It is understood by those skilled in the art that there are various modification examples to the implemented method and apparatus. As described below, a functional block diagram illustrating the charging and discharging control apparatus of each example embodiment indicates not configurations of hardware unit, but blocks of logical functional unit.

The charging and discharging control apparatus 100 does not eliminate a configuration including a plurality of computers 80.

The computer program 90 according to the example embodiment causes the computer 80 for implementing the charging and discharging control apparatus 100 to execute a procedure of supplying electric power to the power storage apparatus 40 when a current is flowing from the AC power line 28b to the power system 22 (at the time of electricity sale).

The computer program 90 of the example embodiment may be stored in a storage medium readable by the computer 80. The storage medium is not particularly limited thereto, and various forms of recording media are conceivable. The program 90 may be loaded from the storage medium into the memory 84 of the computer 80, or may be downloaded to the computer 80 through the network and loaded into the memory 84.

The storage medium for storing the computer program 90 includes a medium usable by the non-transitory tangible computer 80, and program codes readable by the computer 80 are embedded in the medium. When the computer program 90 is executed on the computer 80, the computer program 90 causes the computer 80 to execute the following control method that implements the charging and discharging control apparatus 100.

The method of controlling the charging and discharging control apparatus 100 having such a configuration of the example embodiment will be described below.

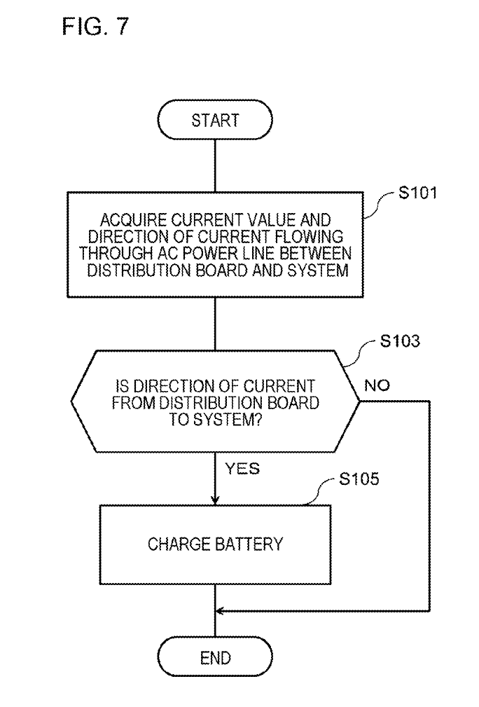

FIG. 7 is a flowchart illustrating an example of operations of the charging and discharging control apparatus 100 according to the example embodiment.

The control method according to the example embodiment of the present invention is a method of controlling the charging and discharging control apparatus 100, and is a control method executed by the computer 80, that implements the charging and discharging control apparatus 100.

The control method according to the example embodiment includes, by the charging and discharging control apparatus 100, acquiring information on the direction of the current in the AC power line 28b (step S101), and supplying electric power to the power storage apparatus 40 when a current is flowing from the AC power line 28b to the power system 22 (at the time of electricity sale) (“YES” in step S103) (step S105).

Hereinafter, this will be described in more detail.

First, the acquisition unit 102 acquires a current value and direction of a current flowing through the AC power line 28b between the distribution board 24 and the power system 22 from the clamp type AC sensor 44 (step S101). Herein, it is considered that when the current is flowing in a direction from the power system 22 to the distribution board 24, the current value is a positive value, and when a current is flowing in a direction from the distribution board 24 to the power system 22, the current value is a negative value.

The control unit 104 determines whether or not the direction of the current is a direction from the distribution board 24 to the power system 22 (step S103). For example, it may be determined whether the current value acquired by the acquisition unit 102 in step S101 is a negative value or not.

In a case where the current is directed from the distribution board 24 to the power system 22 (“YES” in step S103), and for example, the current flowing through the AC power line 28b has a negative value (less than zero), the control unit 104 charges the surplus of electric power derived from the PV panel 12 to the storage battery of the battery system 42 (step S105). Then, the processing is ended.

At this time, the surplus of the electric power generated by the PV panel 12 flows directly from the DC power line 16 to the power storage apparatus 40, and is charged to the storage battery of the battery system 42. As in the example embodiment to be described later, in the configuration in which the power storage apparatus 40 is connected to the AC power line 28a, the surplus of the electric power flows from the PV panel 12 to the power storage apparatus 40 passing through the PV-PCS 14 and the AC power line 28a, and is charged to the storage battery of the battery system 42 in the power storage apparatus 40.

In a case where the current is not directed from the distribution board 24 to the power system 22 (“NO” in step S103), for example, when the current flowing through the AC power line 28b has a positive value (zero or more), the processing will be described in an example embodiment as follows and will not be described herein. Since the stopping condition of charging processing will be also described in the example embodiment as follows, the description thereof will not be described herein.

The processing of the flowchart in FIG. 7 may be repeatedly executed at a predetermined cycle, for example, during the first time zone in which the storage battery may be charged. The processing of each step may be performed asynchronously.

As described above, in the charging and discharging control apparatus 100 of the example embodiment, the acquisition unit 102 acquires the direction of the current in the AC power line 28b, and the control unit 104 supplies electric power to the storage battery of the battery system 42 when a current is flowing from the AC power line 28b to the power system 22 (at the time of electricity sale).

As described above, according to the charging and discharging control apparatus 100 of the example embodiment, with a simple configuration, it is possible to efficiently charge surplus electric power of the PV panel 12 to the storage battery of the battery system 42.

In the example embodiment, since the electric power of the storage battery is supplied only to the specific load, there is no backflow to the power system 22. For example, when connected with the power system 22, application for system interconnection is required, and this is troublesome. However, according to the power storage system 1 of the example embodiment, it is not necessary to perform system interconnection and complicated application procedures required for system interconnection are unnecessary.

### Second Example Embodiment

Next, the power storage system according to a second example embodiment of the present invention will be described below.

The power storage system of the example embodiment has the same configuration as that of the power storage system 1 of the aforementioned example embodiment in FIG. 2, and will be described below with reference to FIG. 2 and FIG. 3.

In the example embodiment, an example of a method of controlling charging and discharging a storage battery in the control unit 104 of the aforementioned example embodiment will be described in detail.

The control unit 104 of the charging and discharging control apparatus 100 of the example embodiment controls charging and discharging of the storage battery according to the direction of the current flowing between the distribution board 24 and the power system 22.

A specific control method will be described below.

In the charging and discharging control apparatus 100 of the example embodiment, the control unit 104 supplies electric power to the power storage apparatus 40 when a current is flowing from the AC power line 28b to the power system 22 (at the time of electricity sale), and causes the power storage apparatus 40 to supply electric power to the specific load 27 when a current is flowing from the power system 22 to the AC power line 28b (at the time of electricity purchase).

Specific examples will be described below.

Herein, it is considered that the current flowing through the AC power line 28b, acquired by the acquisition unit 102, takes a negative value when the current is flowing in the direction from the distribution board 24 to the power system 22, and takes a positive value when the current is flowing in the direction from the power system 22 to the distribution board 24.

The control unit 104 determines whether the current flowing through the AC power line 28b, acquired by the acquisition unit 102, is positive or negative. When the current value is negative (current value<0), the control unit 104 increases a charging current value by a predetermined value (for example, 1 A) to charge the storage battery. Thereafter, the acquisition unit 102 acquires the current value of the current flowing through the AC power line 28b, and the determination processing is repeated until the current value reaches zero.

When the current value is positive (current value>0), the control unit 104 increases a discharging current value by a predetermined value (for example, 1 A) to discharge the storage battery. Thereafter, the acquisition unit 102 acquires the current value of the current flowing through the AC power line 28b, and the determination processing is repeated until the current value reaches zero.

When the current becomes zero, the control unit 104 continues to charge and discharge the storage battery with the current value at that time. The direction of the current between the distribution board 24 and the power system 22 is monitored again.

Also, in the example embodiment, by reading out and executing the program 90 stored in the storage 85 to the memory 84, the CPU 82 of the computer 80 in FIG. 6 may implement each function of each unit of the charging and discharging control apparatus 100 in FIG. 3.

The computer program 90 according to the example embodiment causes the computer 80 for implementing the charging and discharging control apparatus 100 to execute a procedure of acquiring information on the direction of the current in the AC power line 28b, a procedure of supplying electric power to the power storage apparatus 40 when a current is flowing from the AC power line 28b to the power system 22 (at the time of electricity sale), and a procedure of causing the power storage apparatus 40 to supply electric power to the specific load 27 when a current is flowing from the power system 22 to the AC power line 28b (at the time of purchase).

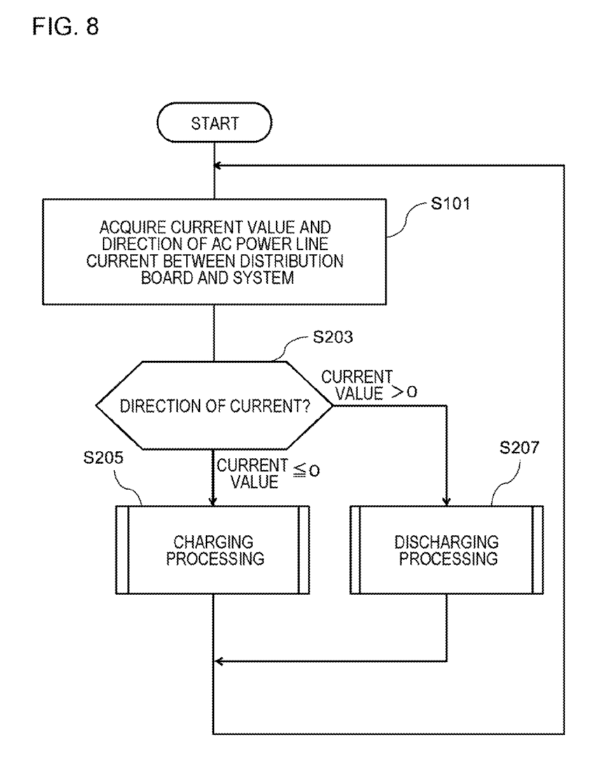

A method of controlling the charging and discharging control apparatus 100 according to the example embodiment will be described below with reference to FIG. 8 to FIG. 10.

FIG. 8 is a flowchart illustrating an example of operations of the charging and discharging control apparatus 100 according to the example embodiment.

The control method according to the example embodiment of the present invention is a method of controlling the charging and discharging control apparatus 100, the method executed by the computer 80, that implements the charging and discharging control apparatus 100.

The control method according to the example embodiment includes, by the charging and discharging control apparatus 100, acquiring information on the direction of the current in the AC power line 28b (step S101), determining the direction of the current in the AC power line 28b (step S103), supplying electric power to the power storage apparatus 40 (charging processing in step S205) when the current is flowing from the AC power line 28b to the power system 22 (at the time of electricity sale) (current value<0 in step S103), and causing the power storage apparatus 40 to supply electric power to the specific load 27 (discharging processing in step S207) when the current is flowing from the power system 22 to the AC power line 28b (at the time of electricity purchase)(current value>0 in step S203).

Hereinafter, this will be described in more detail.

First, the acquisition unit 102 acquires a current value and direction of a current flowing through the AC power line 28b between the distribution board 24 and the power system 22 from the clamp type AC sensor 44 (step S101). Herein, it is considered that when the current is flowing in a direction from the power system 22 to the distribution board 24, the current value is a positive value, and when a current is flowing in a direction from the distribution board 24 to the power system 22, the current value is a negative value.

The control unit 104 acquires the current value and the direction of the current flowing through the AC power line 28a between the distribution board 24 and the power system 22 (step S101). The direction of the current is determined (step S203). For example, the direction of the current may be determined by the positive or negative of the current value acquired by the acquisition unit 102 in step S101. In the example embodiment, it is determined whether the current value is equal to or less than zero (zero or a negative value), or the current value is more than zero (a positive value).

When the current is directed from the distribution board 24 to the power system 22 (current value<0 in step S203), this means that the power generation amount of the PV panel 12 exceeds the total consumption amount of the general load 26 and the specific load 27, and surplus electric power of the PV panel 12 is generated. When the current value in step S203 is zero, this means that the power generation amount of the PV panel 12 is equal to the total consumption amount of the general load 26 and the specific load 27, or there is a possibility that surplus electric power of the PV panel 12 is generated.

For example, an electric power amount of a hatched portion in which the power generation amount of the PV panel 12, indicated by the solid line in FIG. 4, exceeds the total consumption amount of the general load 26 and the specific load 27, indicated by the broken line, is surplus electric power. This surplus electric power is sold.

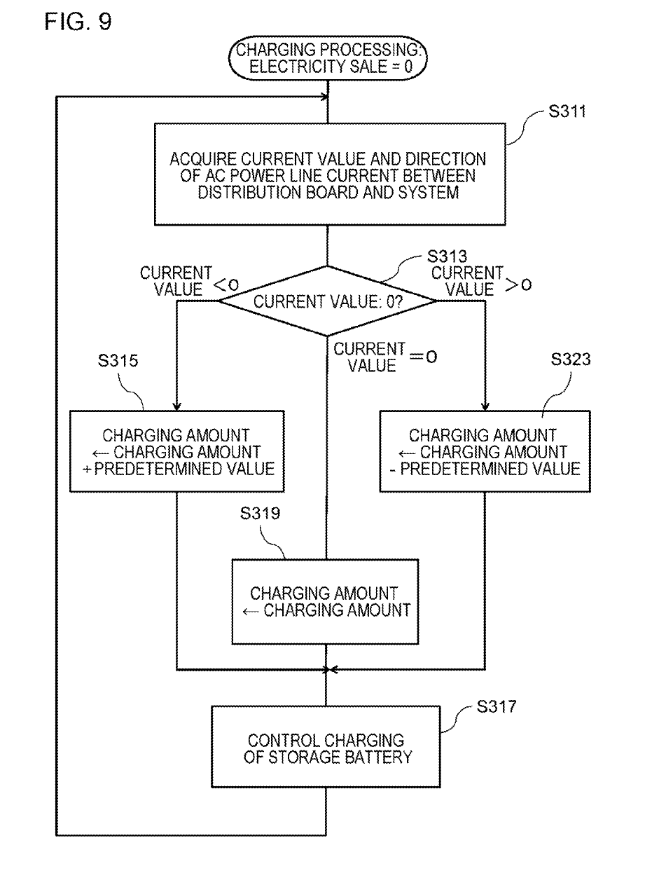

In the example embodiment, when the current is directed from the distribution board 24 to the power system 22 (current value<0 in step S203), that is, when electricity sale occurs, an operation is performed in which the surplus electric power is not sold but is charged to the storage battery. Herein, a charging processing routine in FIG. 9 is executed.

When the current is directed from the power system 22 to the distribution board 24 (current value>0 in step S203), this means that the power generation amount of the PV panel 12 falls below the total consumption amount of the general load 26 and the specific load 27, a power shortage occurs, and electricity purchase from the power system 22 occurs.

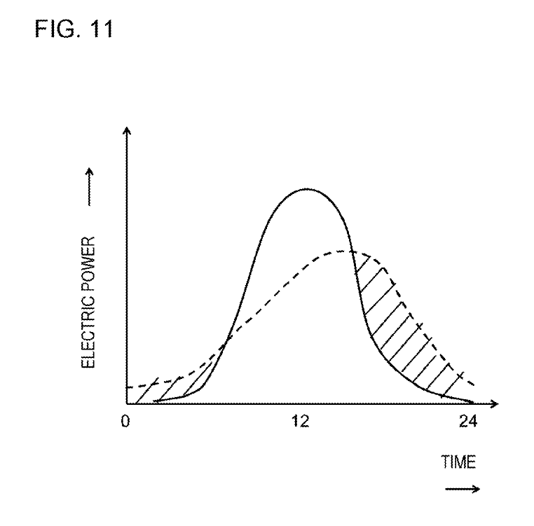

For example, an electric power amount of a hatched portion in which a power generation amount of the PV panel 12, indicated by a solid line in FIG. 11, falls below a total consumption amount of the general load 26 and the specific load 27, indicated by a broken line, is a shortage. This shortage is purchased from the power system 22. Alternatively, in a dischargeable time zone, the storage battery of the battery system 42 may be discharged to compensate for the shortage.

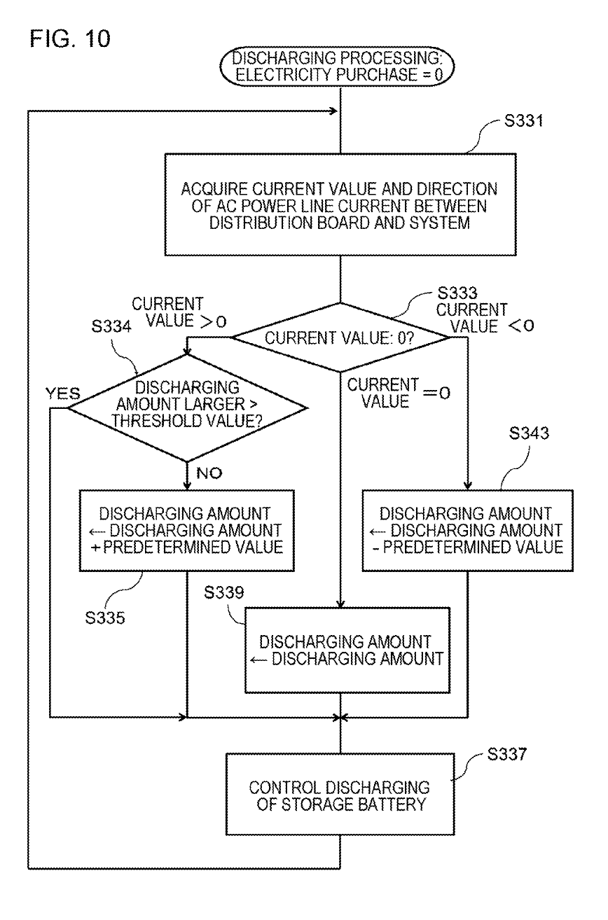

In the example embodiment, when the current is directed from the power system 22 to the distribution board 24 (current value>0 in step S203), that is, when the electricity purchase occurs, an operation is performed in which a shortage of electric power is not purchased but is discharged from the storage battery. Herein, a discharging processing routine in FIG. 10 is executed.

After step S205 and step S207, the processing returns to step S101. The processing of the flowchart in FIG. 8 is repeatedly executed at a predetermined cycle.

Next, the charging processing in step S205 of FIG. 8 will be described in detail below.

FIG. 9 is a flowchart illustrating an example of detailed procedures of the charging processing of the charging and discharging control apparatus 100 according to the example embodiment. In this processing, surplus electric power generated by the PV panel 12 is charged to the storage battery so that electricity sale becomes zero.

First, the acquisition unit 102 acquires a current value and direction of a current flowing through the AC power line 28b between the distribution board 24 and the power system 22 (step S311). The control unit 104 determines whether the current value is larger than zero (a positive value), the current value is equal to zero, or the current value is smaller than zero (a negative value) (step S313).

In a case where the current value is smaller than zero in step S313, the control unit 104 increases a charging amount at the time of charging the surplus of electric power derived from the PV panel 12 to the storage battery of the battery system 42, by a predetermined value (step S315). The set charging amount is charged to the storage battery (step S317). Thereafter, the processing returns to step S311 and is repeated.

Therefore, while the current value is smaller than zero in step S313, the charging amount is increased by the predetermined value, and is charged to the storage battery.

This is repeated until the current value reaches zero, and when the current value is zero in step S313, the charging amount is set as it is (step S319), and the storage battery is charged with the set charging amount (step S317). Thereafter, the processing returns to step S311 and is repeated.

Based on the current value of the AC power line 28b acquired in step S311, when the current value is larger than zero, the control unit 104 decreases the charging amount at the time of charging the storage battery of the battery system 42, by a predetermined value (step S323). The set charging amount is charged to the storage battery (step S317). Thereafter, the processing returns to step S311 and is repeated.

This is repeated until the current value reaches zero, and when the current value is zero in step S313, the charging amount is set as it is (step S319), and the storage battery is charged with the set charging amount (step S317). Thereafter, the processing returns to step S311 and is repeated.

As described above, in the example embodiment, while electricity sale is occurring, the charging processing in FIG. 9 is repeatedly performed so that the electricity sale becomes zero.

In this manner, during the charging processing, the storage battery is charged with the charging amount out of the power generation amount of the PV panel 12 to eliminate electricity sale to the power system 22. As a result, the storage battery is charged with surplus electric power in the hatched portion of FIG. 4.

In the power storage system 1 of FIG. 2, the surplus of the electric power generated by the PV panel 12 flows from the PV panel 12 to the power storage apparatus passing through the PV-PCS 14 and the AC power line 28a, and is charged to the storage battery of the battery system 42 in the power storage apparatus.

Next, the discharge processing in step S207 of FIG. 8 will be described in detail below.

FIG. 10 is a flowchart illustrating an example of detailed procedures of the discharging processing of the charging and discharging control apparatus 100 according to the example embodiment. In this processing, electric power is supplied from the storage battery to the specific load 27 to reduce electricity purchase.

First, the acquisition unit 102 acquires the current value and direction of the current flowing through the AC power line 28b between the distribution board 24 and the power system 22 (step S331). Thereafter, the processing returns to step S331 and is repeated.

Therefore, in a case where the current value is larger than zero in step S333, the control unit 104 increases a discharging amount at the time of discharging the shortage of electric power from the storage battery of the battery system 42, by a predetermined value (step S335). The storage battery is discharged with the set discharging amount (step S337). Thereafter, the processing returns to step S331 and is repeated.

Here, the total power consumption amount of the specific load 27 is set as a threshold value, and the discharging amount is increased up until the discharging amount is equal to or less than the threshold value. Therefore, when the discharging amount exceeds the threshold value (“YES” in step S334), the discharging amount is set as it is, and the processing bypasses step S335 and proceeds to step S337. In a case where the discharging amount is equal to or less than the threshold value (“NO” in step S334), the processing proceeds to step S335.

The storage battery is discharged with the set discharging amount (step S337). Thereafter, the processing returns to step S331 and is repeated.

Therefore, under the condition of the current value>0 in step S333, the discharging amount is increased by the predetermined value up until the discharging amount reaches the total power consumption amount of the specific load 27, and is discharged from the storage battery.

This is repeated until the current value reaches zero or the total power consumption amount of the specific load 27 is reached. When the current value becomes zero in step S333, the discharging amount is set as it is (step S339) and the storage battery is charged with the set charging amount (step S337). Thereafter, the processing returns to step S331.

As the threshold value, a predetermined set value may be stored in the storage apparatus 110 in advance, or the set value may be updated as necessary. A configuration may be provided to allow to set a threshold value based on an actual measured value by further providing an acquisition unit (not illustrated) for acquiring the power consumption amount of the specific load 27.

Based on the current value of the AC power line 28b acquired in step S331, when the current value is equal to or less than zero, the control unit 104 decreases the discharging amount discharged from the storage battery of the battery system 42, by a predetermined value (step S343). The storage battery is discharged with the set discharging amount (step S337). Thereafter, the processing returns to step S331.

This is repeated until the current value reaches zero, and when the discharging amount becomes zero (“NO” in step S341), the discharging amount is set as it is (step S339), and the storage battery is discharged at the set discharging amount (step S337). Thereafter, the processing returns to step S331.

As described above, in the example embodiment, as the electricity purchase is occurring, the discharging processing in FIG. 10 is repeatedly performed so that the electricity purchase becomes zero.

In this manner, during the discharging processing, electric power is discharged from the storage battery to the specific load 27 to eliminate electricity sale to the power system 22 or electric power is discharged from the battery to the specific load 27 up to the total consumption amount of the specific load 27. As a result, the insufficient electric power of the hatched portion in FIG. 11 is discharged from the storage battery and supplied to the specific load 27.

In the power storage system 1 of FIG. 2, the electric power stored in the storage battery as the surplus of the PV panel 12 is supplied from the power storage apparatus 40 to the DC power line 16 and supplied to the specific load 27 through the PV-PCS 14, the AC power line 28a, and the distribution board 24.

In another example embodiment, in a case where the power storage apparatus 40 is connected to the AC power line 28a, the electric power stored in the storage battery is supplied from the power storage apparatus to the specific load 27 through the distribution board 24.

The processing of each step of the flowchart in FIG. 8 may be performed asynchronously. For example, in the case where the electricity sale is detected in step S203, the processing in step S205 may be executed only during the first time zone in which the storage battery may be charged. On the other hand, in the case where the electricity purchase is detected in step S203, the processing in step S207 may be executed only during the second time zone in which the storage battery may be discharged.

Alternatively, the charging processing in FIG. 9 may be performed only during the first time zone and the discharging processing in FIG. 10 may be performed only during the second time zone. The processing at the time of charging and the processing at the time of discharging processing may be executed asynchronously in separate routines.

As described above, in the power storage system 1 of the example embodiment, when a current is flowing in the direction from the distribution board 24 to the power system 22, the control unit 104 causes the charging amount to the storage battery to be increased up until the current becomes zero. While a current is flowing in the direction from the power system 22 to the distribution board 24, the control unit 104 causes the discharging amount from the storage battery to be increased up until the current becomes zero.

According to this configuration, the same effect as in the aforementioned example embodiment may be obtained, and in a case where the power generation amount from the PV panel 12 exceeds the total consumption amount of the general load 26 and the specific load 27, the surplus electric power may be charged to the storage battery so that electricity sale does not occur, and in a case where the power generation amount from the PV panel 12 falls below the total consumption amount of the general load 26 and the specific load 27, the shortage may be discharged from the storage battery so that electricity purchase does not occur.

As described above, according to the example embodiment, the power storage system 1 may efficiently charge and discharge electric power. Further, the power storage system 1 of the example embodiment is not required to perform system interconnection, and also has the effect of eliminating the complicated application procedures required for system interconnection.

As described above, although the example embodiments of the present invention have been described with reference to the drawings, they are an example of the present invention, and various configurations may be adopted in addition to those as described above.

For example, in the aforementioned example embodiments, there has been described an example in which the DC power generation apparatus is a photovoltaic power generation facility and the conversion apparatus is a Photovoltaics Power Conditioning System (PV-PCS) (Photovoltaics power conditioner).

The DC power generation apparatus may include at least one of a photovoltaic power generation facility, a fuel cell, and a private power generation facility utilizing fossil energy.

(Charging of PV Power Output Suppression Surplus Electric Power)

Further, in still another example embodiment, surplus electric power controlled to suppress power output in response to the PV power output suppression signal may be charged.

In a case where the PV-PCS 14 receives the power output suppression control signal for the PV panel 12, there is a possibility that the electric power amount is controlled to be suppressed to be lower than the actual electric power amount generatable by the PV panel 12 by the PV-PCS 14.

Here, the PV power output suppression signal includes, for example, an instruction to suppress an output at a predetermined ratio (%) of the rated power output of the PV-PCS 14.

In the present invention, the suppressed electric power is also charged to the storage battery as surplus electric power.

The control unit charges a predetermined amount of the output from the PV panel 12 to the storage battery. At this time, a clamp type DC sensor (not illustrated) is electrically connected to the DC power line 16 between the connection position of the power storage apparatus 40 and the PV-PCS 14, or a clamp type AC sensor (not illustrated) is electrically connected to the AC power line 28 between the PV-PCS 14 and the distribution board 24. The acquisition unit acquires the current value measured by the sensor. The control unit monitors an increase or decrease in the current value. In a case where the current value is decreased, it is determined that there is no surplus electric power. In a case where the current value is not decreased, it is determined that there is surplus electric power.

According to this configuration, since it is possible to charge a PV power output suppressed surplus electric power, the electric power generated by the PV panel 12 may be efficiently charged without waste.

(Charging of Electricity Sale Amount)

Further, in still another example embodiment, in a case where a backflow (electricity sale) to the power system 22 occurs, the storage battery is charged.

In this configuration, the acquisition unit acquires the value of the meter reading data (a consumption amount of electric power, backflow value) and the like from the smart meter (not illustrated) of the customer or a Home Energy Management System (HEMS) (not illustrated). In the example embodiment, the acquisition unit may have a configuration for wirelessly communicating with a smart meter or HEMS using the communication I/F 87 in FIG. 6.

According to this configuration, it is possible to efficiently charge the storage battery with electric power which is otherwise sold with a simple configuration.

### EXAMPLE

### First Example

An example of the charging and discharging control apparatus 300 according to the present invention will be described below.

In the charging and discharging control apparatus 300 of the present example, a specific example will be described of a configuration allowing to supply electric power to the specific load 27, to which electric power may be supplied from the storage battery, by switching between the power system 22 and the storage battery (battery system 42).

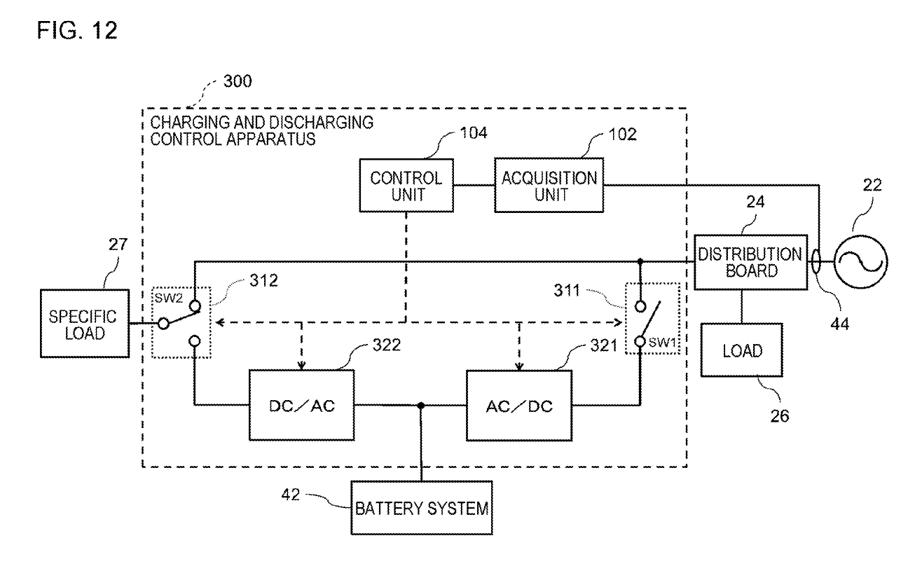

FIG. 12 is a schematic block diagram illustrating a configuration example of the charging and discharging control apparatus 300 according to the example of the present invention.

The charging and discharging control apparatus 300 includes an acquisition unit 102, a control unit 104, a first switch 311 (indicated as “SW 1” in the figure), a second switch 312 (indicated as “SW 2” in the figure), an AC/DC (alternating-current/direct-current) converter 321, and a DC/AC (direct-current/alternating-current) converter 322.

The battery system 42 may supply electric power only to the specific load 27.

The AC/DC converter 321 is connected between the AC power line 28b and the battery system 42. The AC/DC converter 321 converts AC power into DC power.

The DC/AC converter 322 is connected between the battery system 42 and the specific load 27. The DC/AC converter 322 converts DC power into AC power.

The first switch 311 turns on or off a connection between the AC power line 28 and the battery system 42 through the AC/DC converter 321.

The second switch 312 connects the specific load 27 to one of the AC power line 28 and the battery system 42 through the DC/AC converter 322.

When supplying electric power from the power system 22 to the specific load 27, the control unit 104 of the charging and discharging control apparatus 300 connects the specific load 27 to the AC power line 28a by the second switch 312.

When supplying electric power from the battery system 42 to the specific load 27, the control unit 104 of the charging and discharging control apparatus 300 connects the specific load 27 to the battery system 42 by the second switch 312.

In a case where the battery system 42 is charged with electric power generated by the DC power generation apparatus (PV panel 12), the battery system 42 is connected to the AC power line 28b by the first switch 311.

During the first time zone, the specific load 27 is connected to the AC power line 28a by the second switch 312. When the current is flowing in the direction from the distribution board 24 to the power system 22 (electricity sale) or when the current is zero, the AC/DC converter 321 is connected to the AC power line 28 by the first switch 311 and the battery system 42 is charged. In a case of full charge, the first switch 311 is not connected to the AC power line 28 and the AC/DC converter 321.

During the second time zone, the first switch 311 is turned off and the specific load 27 is connected to the battery system 42 by the second switch 312. When the remaining power storage capacity of the storage battery is smaller than the first threshold value or the available capacity is equal to or larger than the second threshold value, the specific load 27 is connected to the AC power line 28a by the second switch 312.

In this manner, the control unit 104 controls the first switch 311, the second switch 312, the AC/DC converter 321, and the DC/AC converter 322 in consideration of a chargeable time zone or dischargeable time zone, a direction of the current between the power system 22 and the distribution board 24, and a value of the remaining battery amount, thereby controlling charging and discharging of the storage battery.

### Second Example: Switching Configuration to/from UPS Mode

A charging and discharging control apparatus according to another example embodiment of the present invention will be described with respect to a configuration example in which switching between a general Uninterruptible Power Supply (UPS) mode and a storage battery mode may be used.

The configuration of the main unit of hardware is the same as that of the first example.

A mode switching unit may be provided as a hardware changeover switch or may be provided as a software setting screen so that the modes are switchable by receiving a user operation.

In this configuration, it is possible to set the UPS mode by appropriately connecting the first switch 311 and the second switch 312 in the constitution of the first example. Further, according to the way of connection, it is possible to utilize a plurality of electric power feed systems.

According to this configuration, since most of the structure may be shared with the UPS, it is possible to implement a charging and discharging control apparatus for efficiently utilizing the PV surplus electric power at a low cost.

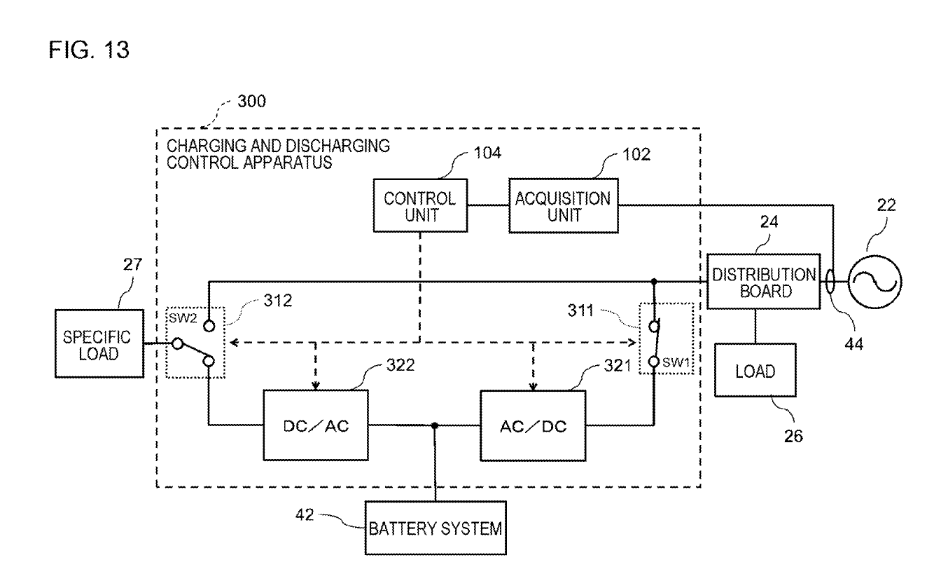

For example, in the configuration of the first example, as illustrated in FIG. 13, it is also possible to use the apparatus as a UPS by turning on the first switch and connecting the second switch to a DC/AC converter 322 side. In this case, it is possible to supply electric power from the storage battery (battery system 42) to the specific load 27 without instantaneous interruption at power failure, similarly to a normal inverter feed system which is a general UPS electric power feed system.

While the present invention has been particularly shown and described with reference to the example embodiments and examples thereof, the present invention is not limited thereto. It will be understood by those of ordinary skill in the art that various changes in configuration and details may be made therein without departing from the scope of the present invention.

Note that, when information on the user is obtained and utilized in the present invention, the obtaining and the utilizing are to be lawfully performed.

Hereinafter, examples of a reference embodiment will be supplementally described.

1. A charging and discharging control apparatus which controls charging and discharging of a power storage apparatus, the power storage apparatus being connected to an AC power line, and

the AC power line being connected to a power system, being connected to a DC power generation apparatus through a DC/AC conversion apparatus, and being connectable to a load, the charging and discharging control apparatus, including:

an acquisition unit that acquires information on a direction of a current in the AC power line; and

a control unit that supplies electric power to the power storage apparatus when a current is flowing from the AC power line to the power system.

2. The charging and discharging control apparatus according to 1, in which the control unit supplies the electric power discharged from the power storage apparatus to the specific load during a predetermined time zone.

3. The charging and discharging control apparatus according to 2, in which the control unit supplies electric power supplied from the power system to the specific load, except during a predetermined time zone.

4. The charging and discharging control apparatus according to any one of 1 to 3, in which the control unit causes the power storage apparatus to supply electric power to the specific load when a current is flowing from the power system to the AC power line.

5. The charging and discharging control apparatus according to any one of 1 to 4, further including:

a first switch, a second switch, an AC/DC converter, and a DC/AC converter,

in which the power storage apparatus is capable of supplying electric power to a specific load without involving the AC power line,

the AC/DC converter is connected between the AC power line and the power storage apparatus,

the DC/AC converter is connected between the power storage apparatus and the specific load,

the first switch turns on or off a connection between the AC power line and the power storage apparatus through the AC/DC converter,

the second switch connects the specific load to any one of the AC power line and the power storage apparatus through the DC/AC converter, and

the charging and discharging control apparatus is configured to

connect the specific load to the AC power line by the second switch when electric power is supplied from the power system to the specific load,

connect the specific load to the power storage apparatus by the second switch when electric power is supplied from the power storage apparatus to the specific load, and

connect the AC power line and the power storage apparatus by the first switch when the electric power generated by the DC power generation apparatus is supplied to the power storage apparatus through the AC power line.

6. The charging and discharging control apparatus according to any one of 1 to 5, in which the DC power generation apparatus includes at least one of a photovoltaic power generation facility, a fuel cell, and a private power generation facility utilizing fossil energy.

7. The charging and discharging control apparatus according to any one of 1 to 6, in which the DC power generation apparatus is a photovoltaic power generation facility, and the DC/AC conversion apparatus is a Photovoltaics Power Conditioning System (PV-PCS) (Photovoltaics power conditioner).

8. A control method performed by a charging and discharging control apparatus connected to a power storage apparatus capable of charging electricity generated by a DC power generation apparatus, the power storage apparatus being connected to an AC power line, and is capable of supplying electric power to a specific load without involving the AC power line, and the AC power line being connected to a power system, being connected to the DC power generation apparatus through a DC/AC conversion apparatus, and being connectable to a general load, the control method performed by the charging and discharging control apparatus including

supplying electric power to the power storage apparatus when a current is flowing from the AC power line to the power system.

9. The control method performed by the charging and discharging control apparatus according to 8, further including

supplying electric power discharged from the power storage apparatus to the specific load during a predetermined time zone.

10. The control method performed by the charging and discharging control apparatus according to 9, further including

supplying electric power supplied from the power system to the specific load, except during a predetermined time zone.

11. The control method performed by the charging and discharging control apparatus according to any one of 8 to 10, further including

causing the power storage apparatus to supply electric power to the specific load when a current is flowing from the power system to the AC power line.

12. The control method performed by the charging and discharging control apparatus according to any one of 8 to 11, the charging and discharging control apparatus including a first switch, a second switch, an AC/DC converter, and a DC/AC converter, the power storage apparatus being capable of supplying electric power to a specific load without involving the AC power line, the AC/DC converter being connected between the AC power line and the power storage apparatus, the DC/AC converter being connected between the power storage apparatus and the specific load, the first switch turning on or off a connection between the AC power line and the power storage apparatus through the AC/DC converter, the second switch connecting the specific load to any one of the AC power line and the power storage apparatus through the DC/AC converter, the control method performed by the charging and discharging control apparatus, further including:

connecting the specific load to the AC power line by the second switch when electric power is supplied from the power system to the specific load,

connecting the specific load to the power storage apparatus by the second switch when electric power is supplied from the power storage apparatus to the specific load, and

connecting the AC power line and the power storage apparatus by the first switch when the electric power generated by the DC power generation apparatus is supplied to the power storage apparatus through the AC power line,

13. The control method performed by the charging and discharging control apparatus according to any one of 8 to 12,

in which the DC power generation apparatus includes at least one of a photovoltaic power generation facility, a fuel cell, and a private power generation facility utilizing fossil energy.

14. The control method performed by the charging and discharging control apparatus according to any one of 8 to 13,

in which the DC power generation apparatus is a photovoltaic power generation facility, and

the DC/AC conversion apparatus is a Photovoltaics Power Conditioning System (PV-PCS) (Photovoltaics power conditioner).

15. A program of a computer that implements a charging and discharging control apparatus connected to a power storage apparatus capable of charging electricity generated by a DC power generation apparatus, the power storage apparatus being connected to an AC power line, and being capable of supplying electric power to a specific load without involving the AC power line, and the AC power line being connected to a power system, being connected to the DC power generation apparatus through a DC/AC conversion apparatus, and being connectable to a general load, the program, causing: the computer to execute a procedure of supplying electric power to the power storage apparatus when a current is flowing from the AC power line to the power system.

16. The program described in 15, wherein the program causes the computer to execute a procedure of supplying electric power discharged from the power storage apparatus to the specific load during a predetermined time zone.

17. The program described in 16, wherein the program causes the computer to execute a procedure of supplying electric power supplied from the power system to the specific load, except during a predetermined time zone.

18. The program described in any one of 15 to 17, wherein the program causes the computer to execute a procedure of supplying electric power from the power storage apparatus to the specific load when a current is flowing from the power system to the AC power line program.

19. The program described in any one of 15 to 18, the charging and discharging control apparatus including a first switch, a second switch, an AC/DC converter, and a DC/AC converter, the power storage apparatus being capable of supplying electric power to a specific load without involving the AC power line, the AC/DC converter being connected between the AC power line and the power storage apparatus, the DC/AC converter being connected between the power storage apparatus and the specific load, the first switch turning on or off a connection between the AC power line and the power storage apparatus through the AC/DC converter,

the second switch connecting the specific load to any one of the AC power line and the power storage apparatus through the DC/AC converter,

the program causing: the computer to execute

a procedure of connecting the specific load to the AC power line by the second switch when electric power is supplied from the power system to the specific load,

a procedure of connecting the specific load to the power storage apparatus by the second switch when electric power is supplied from the power storage apparatus to the specific load, and

a procedure of connecting the AC power line and the power storage apparatus by the first switch when electric power generated by the DC power generation apparatus is supplied to the power storage apparatus through the AC power line.

20. The program described in any one of 15 to 19, in which the DC power generation apparatus includes at least one of a photovoltaic power generation facility, a fuel cell, and a private power generation facility utilizing fossil energy.

21. The program described in any one of 15 to 20, in which the DC power generation apparatus is a photovoltaic power generation facility, and

the DC/AC conversion apparatus is a Photovoltaics Power Conditioning System (PV-PCS) (Photovoltaics power conditioner).

22. A power storage system including:

a power storage unit, and

a control unit that controls charging and discharging of the power storage unit,

in which the power storage unit is connected to an AC power line and is capable of supplying electric power to a specific load without involving the AC power line,

the AC power line is connected to a power system, is connected to a DC power generation apparatus through a DC/AC conversion apparatus, and is connectable to a general load, and

the control unit supplies electric power to the power storage unit as a current is flowing from the AC power line to the power system.

23. The power storage system described in 22, in which the control unit supplies electric power discharged from the power storage unit to the specific load during a predetermined time zone.

24. The power storage system described in 23, in which the control unit supplies electric power supplied from the power system to the specific load, except during a predetermined time zone.

25. The power storage system described in any one of 22 to 24, in which the control unit causes the power storage unit to supply electric power to the specific load when a current is flowing from the power system to the AC power line.

26. The power storage system described in any one of 22 to 25, in which the control unit includes a first switch, a second switch, an AC/DC converter and a DC/AC converter,

the power storage unit is capable of supplying electric power to a specific load without involving the AC power line,

the AC/DC converter is connected between the AC power line and the power storage unit,

the DC/AC converter is connected between the power storage unit and the specific load,

the first switch turns on or off a connection between the AC power line and the power storage unit through the AC/DC converter,

the second switch connects the specific load to any one of the AC power line and the power storage unit through the DC/AC converter, and

the control unit is configured to connect the specific load to the AC power line by the second switch when electric power is supplied from the power system to the specific load,

connect the specific load to the power storage unit by the second switch when electric power is supplied from the power storage unit to the specific load, and

connect the AC power line and the power storage unit by the first switch when electric power generated by the DC generation apparatus is supplied to the power storage unit through the AC power line.

27. The power storage system described in any one of 22 to 26, in which the DC power generation apparatus includes at least one of a photovoltaic power generation facility, a fuel cell, and a private power generation facility utilizing fossil energy.

28. The power storage system described in any one of 22 to 27, in which the DC power generation apparatus is a photovoltaic power generation facility, and

the DC/AC conversion apparatus is a Photovoltaics Power Conditioning System (PV-PCS) (Photovoltaics power conditioner).

This application claims priority based on Japanese Patent Application No. 2016-059286 filed on Mar. 23, 2016, the disclosure of which is incorporated herein in its entirety.

1. A power storage system comprising:
a power storage unit; and
a control unit that controls charging and discharging of the power storage unit,
wherein the power storage unit is connected to an AC power line and is capable of supplying electric power to a specific load without involving the AC power line,
the AC power line is connected to a power system, is connected to a DC power generation apparatus through a DC/AC conversion apparatus, and is connectable to a general load, and
the control unit supplies electric power to the power storage unit when a current is flowing from the AC power line to the power system.

2. The power storage system according to claim 1,
wherein the control unit supplies the electric power discharged from the power storage unit to the specific load during a predetermined time zone.

3. The power storage system according to claim 2,
wherein the control unit supplies the electric power supplied from the power system to the specific load, except during a predetermined time zone.

4. The power storage system according to claim 1,
wherein the control unit causes the power storage unit to supply electric power to the specific load when a current is flowing from the power system to the AC power line.

5. The power storage system according to claim 1,
wherein the control unit comprises a first switch, a second switch, an AC/DC converter and a DC/AC converter, and
the power storage unit is capable of supplying electric power to a specific load without involving the AC power line,
the AC/DC converter is connected between the AC power line and the power storage unit,
the DC/AC converter is connected between the power storage unit and the specific load,
the first switch turns on or off a connection between the AC power line and the power storage unit through the AC/DC converter,
the second switch connects the specific load to any one of the AC power line and the power storage unit through the DC/AC converter, and
the control unit is configured to
connect the specific load to the AC power line by the second switch when electric power is supplied from the power system to the specific load,
connect the specific load to the power storage unit by the second switch when electric power is supplied from the power storage unit to the specific load, and
connect the AC power line and the power storage unit by the first switch when electric power generated by the DC power generation apparatus is supplied to the power storage unit through the AC power line.

6. The power storage system according to claim 1,
wherein the DC power generation apparatus comprises at least one of a photovoltaic power generation facility, a fuel cell, and a private power generation facility utilizing fossil energy.

7. The power storage system according to claim 1,
wherein the DC power generation apparatus is a photovoltaic power generation facility, and
the DC/AC conversion apparatus is a Photovoltaics Power Conditioning System (PV-PCS) (Photovoltaics power conditioner).

8. A charging and discharging control apparatus that controls charging and discharging of a power storage apparatus,
the power storage apparatus being connected to an AC power line, and
the AC power line being connected to a power system, being connected to a DC power generation apparatus through a DC/AC conversion apparatus, and being connectable to a load,
the charging and discharging control apparatus comprising:
an acquisition unit that acquires information on a direction of a current in the AC power line; and
a control unit that supplies electric power to the power storage apparatus when a current is flowing from the AC power line to the power system.

9. The charging and discharging control apparatus according to claim 8,
wherein the control unit supplies the electric power discharged from the power storage apparatus to the specific load during a predetermined time zone.

10. The charging and discharging control apparatus according to claim 9,
wherein the control unit supplies electric power supplied from the power system to the specific load, except during a predetermined time zone.

11. The charging and discharging control apparatus according to claim 8,
wherein the control unit causes the power storage apparatus to supply electric power to the specific load when a current is flowing from the power system to the AC power line.

12. The charging and discharging control apparatus according to claim 8, further comprising:
a first switch, a second switch, an AC/DC converter, and a DC/AC converter,
wherein the power storage apparatus is capable of supplying electric power to a specific load without involving the AC power line,
the AC/DC converter is connected between the AC power line and the power storage apparatus,
the DC/AC converter is connected between the power storage apparatus and the specific load,
the first switch turns on or off a connection between the AC power line and the power storage apparatus through the AC/DC converter,
the second switch connects the specific load to any one of the AC power line and the power storage apparatus through the DC/AC converter, and
the charging and discharging control apparatus is configured to
connect the specific load to the AC power line by the second switch when electric power is supplied from the power system to the specific load,
connect the specific load to the power storage apparatus by the second switch when electric power is supplied from the power storage apparatus to the specific load, and
connect the AC power line and the power storage apparatus by the first switch when the electric power generated by the DC power generation apparatus is supplied to the power storage apparatus through the AC power line.

13. The charging and discharging control apparatus according to claim 8,
wherein the DC power generation apparatus comprises at least one of a photovoltaic power generation facility, a fuel cell, and a private power generation facility utilizing fossil energy.

14. The charging and discharging control apparatus according to claim 8,
wherein the DC power generation apparatus is a photovoltaic power generation facility, and the DC/AC conversion apparatus is a Photovoltaics Power Conditioning System (PV-PCS) (Photovoltaics power conditioner).

15. A control method performed by a charging and discharging control apparatus, the charging and discharging control apparatus being connected to a power storage apparatus capable of charging electricity generated by a DC power generation apparatus,
the power storage apparatus being connected to an AC power line, and being capable of supplying electric power to a specific load without involving the AC power line, and
the AC power line being connected to a power system, being connected to the DC power generation apparatus through a DC/AC conversion apparatus, and being connectable to a general load,
the control method performed by the charging and discharging control apparatus comprising
supplying electric power to the power storage apparatus when a current is flowing from the AC power line to the power system.

16. The control method performed by the charging and discharging control apparatus according to claim 15, further comprising
supplying electric power discharged from the power storage apparatus to the specific load during a predetermined time zone.

17. The control method performed by the charging and discharging control apparatus according to claim 16, further comprising
supplying electric power supplied from the power system to the specific load, except during a predetermined time zone.

18. The control method performed by the charging and discharging control apparatus according to claim 15, further comprising
causing the power storage apparatus to supply electric power to the specific load when a current is flowing from the power system to the AC power line.

19. The control method performed by the charging and discharging control apparatus according to claim 15,
the charging and discharging control apparatus comprising a first switch, a second switch, an AC/DC converter, and a DC/AC converter,
the power storage apparatus being capable of supplying electric power to a specific load without involving the AC power line,
the AC/DC converter being connected between the AC power line and the power storage apparatus,
the DC/AC converter being connected between the power storage apparatus and the specific load,
the first switch turning on or off a connection between the AC power line and the power storage apparatus through the AC/DC converter, and
the second switch connecting the specific load to any one of the AC power line and the power storage apparatus through the DC/AC converter,
the control method performed by the charging and discharging control apparatus further comprising:
connecting the specific load to the AC power line by the second switch when electric power is supplied from the power system to the specific load;
connecting the specific load to the power storage apparatus by the second switch when electric power is supplied from the power storage apparatus to the specific load; and
connecting the AC power line and the power storage apparatus by the first switch when the electric power generated by the DC power generation apparatus is supplied to the power storage apparatus through the AC power line.

20. The control method performed by the charging and discharging control apparatus according to claim 15,
wherein the DC power generation apparatus comprises at least one of a photovoltaic power generation facility, a fuel cell, and a private power generation facility utilizing fossil energy.

21-28. (canceled)
